(19) United States
(12) Patent Application Publication
(10) Pub. No.: US 2026/0122760 A1
(43) Pub. Date: Apr. 30, 2026

(54) LIQUID COOLED PCB FOR INDUCTIVE POWER TRANSFER & INVERTER ELECTRONICS

(71) Applicant: GM GLOBAL TECHNOLOGY OPERATIONS LLC, Detroit, MI (US)

(72) Inventors: Mark Claywell, Birmingham, MI (US); Roshan Kandanda, Sterling Heights, MI (US)

(73) Assignee: GM GLOBAL TECHNOLOGY OPERATIONS LLC, Detroit, MI (US)

(21) Appl. No.: 18/929,689

(22) Filed: Oct. 29, 2024

(51) Int. Cl. H05K 1/02; B60L 50/52; H02K 11/042; H05K 1/18

(52) U.S. Cl. CPC H05K 1/0203; H02K 11/042; H05K 1/181; B60L 50/52; B60L 2210/40; B60L 2220/12; H05K 2201/064

(57) ABSTRACT

A printed circuit board holder for use in a rotational application including the printed circuit board holder configured to be mechanically affixed at an interior diameter surface to a rotor shaft of an electric motor having at least one fluid channel running from an interior diameter surface to an exterior diameter surface, a printed circuit board mechanically affixed to a planar surface of the holder wherein the printed circuit board has a thermally conductive layer in contact with the printed circuit board holder, a component mounted to the printed circuit board such that the component is positioned over the at least one fluid channel and wherein a thermal energy generated by the component is thermally conducted from the component to a fluid within the at least one fluid channel via the thermally conductive layer.

### INTRODUCTION

The present disclosure generally relates to electric vehicle motors and battery systems, and more particularly relates to a method and apparatus including a novel enclosure housing having integrated cooling passages for printed circuit boards in the power electronics system in a separately excited motor.

Electric motors are used in electric vehicles (EV) to convert electrical energy from the battery into mechanical energy to turn the wheels. Typically, there are two main types of electric motors used in EVs: induction motors and permanent magnet synchronous motors (PMSMs). Induction motors are the most common type of electric motor used in EVs. They are relatively simple and inexpensive to manufacture. Induction motors are also very efficient, and they can provide a high torque output. PMSMs are more expensive than induction motors, but they are also more efficient and offer better performance. PMSMs are often used in high-performance EVs, such as sports cars and racing cars. Modern EVs typically have two electric motors, one for each axle, but some EVs can have a single motor located under the hood or four motors, one for each wheel.

While EV motors are typically driven by three phase alternating current (AC) currents converted from the direct current (DC) voltage supplied by the vehicle battery, a separately excited motor (SEM) is a type of electric motor where the stator winding and armature winding are powered by separate voltage sources. The field and armature currents in an SEM can be adjusted separately, enabling precise control of the motor's performance. By varying the field current, the motor's speed can be adjusted over a wide range. The motor can produce high torque at low speeds, making it suitable for applications requiring high starting torque or frequent speed changes. This allows for independent control of the field current and armature current, providing greater flexibility in adjusting the motor's speed and torque. It is desirable to use SEM technology for use in EVs. Furthermore, other desirable features and characteristics of the present disclosure will become apparent from the subsequent detailed description and the appended claims, taken in conjunction with the accompanying drawings and the foregoing technical field and background.

### SUMMARY

Disclosed herein are vehicle control methods and systems and related electrical systems for provisioning vehicle propulsion systems, methods for making and methods for operating such systems, and motor vehicles and other equipment such as aircraft, trucks, buses, forklifts, construction vehicles and other electric vehicles equipped with battery powered electric motors. By way of example, and not limitation, there are presented various embodiments of systems to provide a novel enclosure housing having integrated cooling passages for printed circuit boards in the power electronics system in an SEM.

In accordance with an aspect of the present disclosure, a printed circuit board holder for use in a rotational application including the printed circuit board holder configured to be mechanically affixed to a rotor shaft of an electric motor having at least one fluid channel running from an interior diameter surface to an exterior diameter surface, a printed circuit board mechanically affixed to a planar surface of the printed circuit board holder wherein the printed circuit board has a thermally conductive layer in contact with the printed circuit board holder, a component mounted to the printed circuit board such that the component is positioned over the at least one fluid channel and wherein a thermal energy generated by the component is thermally conducted from the component to a fluid within the at least one fluid channel via the thermally conductive layer, The printed circuit board holder for use in the rotational application of claim 1, wherein a first cross sectional area of the at least one fluid channel is greater at the interior diameter surface than a second cross sectional area of the at least one fluid channel at the exterior diameter surface.

In accordance with another aspect of the present disclosure, wherein the fluid is an oil.

In accordance with another aspect of the present disclosure, wherein the fluid is a non-conductive coolant.

In accordance with another aspect of the present disclosure, wherein the fluid is a gas.

In accordance with another aspect of the present disclosure, wherein a first width of the at least one fluid channel is the same as a second width of the component.

In accordance with another aspect of the present disclosure, wherein the fluid is pumped into the rotor shaft and exits at a fluid port on the rotor shaft aligned with an interior fluid channel port located on the interior diameter surface of the printed circuit board holder.

In accordance with another aspect of the present disclosure, wherein the at least one fluid channel has a backswept shape.

In accordance with another aspect of the present disclosure, wherein the printed circuit board holder is fabricated from a non-conductive material and has at least one alignment post for aligning the printed circuit board and a plurality of retention hooks for retaining the printed circuit board after the printed circuit board is pressure fit into the printed circuit board holder.

In accordance with another aspect of the present disclosure, a method of thermally regulating a printed circuit board holder for use in a rotational application including mechanically coupling the printed circuit board holder having an interior diameter surface and an exterior diameter surface over a rotor shaft, such that the rotor shaft contacts the interior diameter surface and wherein a fluid port on the rotor shaft aligns with an interior fluid channel port on the interior diameter surface, and wherein the printed circuit board holder further includes a fluid channel running from the interior fluid channel port to an exterior fluid channel port on the exterior diameter surface, affixing a printed circuit board to a first edge of the printed circuit board holder such that a thermally conductive layer of the printed circuit board is in contact with the printed circuit board holder and where a component is mounted to a surface opposite to the thermally conductive layer and wherein the component is positioned on the printed circuit board such that the component located over the fluid channel.

In accordance with another aspect of the present disclosure, wherein an edge of the printed circuit board holder is taller than the printed circuit board with the component.

In accordance with another aspect of the present disclosure, wherein a first slot in the printed circuit board holder and a second slot in the thermally conductive layer of the printed circuit board from the fluid channel.

In accordance with another aspect of the present disclosure, wherein the interior diameter surface has a varying local radius such that a fluid is pressurized at a point of largest local radius and wherein the point of largest local radius is located at the interior fluid channel port.

In accordance with another aspect of the present disclosure, wherein a second printed circuit board is affixed to a second edge of the printed circuit board holder opposite of the printed circuit board.

In accordance with another aspect of the present disclosure, wherein the printed circuit board includes a rectifier for converting an inductively coupled alternating current to a direct current for powering an electromagnet.

In accordance with another aspect of the present disclosure, wherein a first width of the fluid channel is the same as a second width of the component

In accordance with another aspect of the present disclosure, wherein a first cross sectional area of the fluid channel at the interior diameter surface is greater than a second cross sectional area of the fluid channel at the exterior diameter surface.

In accordance with another aspect of the present disclosure, wherein a cooling fluid flows through the fluid channel and wherein the colling fluid is at least one of a gas, an oil and a dielectric coolant.

In accordance with another aspect of the present disclosure, an electric motor including a rotor having a plurality of electromagnets, a printed circuit board holder configured to be mechanically affixed at an interior diameter surface to a rotor shaft of an electric motor having a fluid channel running from the interior diameter surface to an exterior diameter surface, a printed circuit board mechanically affixed to a planar surface of the printed circuit board holder wherein the printed circuit board has a thermally conductive layer in contact with the printed circuit board holder, a rectifier circuit for converting an inductively coupled alternating current to a direct current for powering an electromagnet, wherein the rectifier circuit is mounted to the printed circuit board such that the rectifier circuit is positioned over the fluid channel and wherein a thermal energy generated by the rectifier circuit is thermally conducted from the rectifier circuit to a fluid within the fluid channel via the thermally conductive layer.

In accordance with another aspect of the present disclosure, wherein a first cross sectional area of the fluid channel is greater at the interior diameter surface than a second cross sectional area of the fluid channel at the exterior diameter surface.

### BRIEF DESCRIPTION OF THE DRAWINGS

The exemplary embodiments will hereinafter be described in conjunction with the following drawing figures, wherein like numerals denote like elements, and wherein:

FIG. 1 is illustrative of a vehicle employing one or more electric vehicle motors and battery systems in accordance with various embodiments;

FIG. 2 shows a schematic representation of an EV propulsion system in accordance with various embodiments;

FIG. 3 shows a graphical representation of an electronics package 300 for use on a rotor in an electric motor is shown in accordance with various embodiments;

FIG. 4 shows a graphical representation of a cross section of the PCB holder in accordance with various embodiments

FIG. 5 shows a graphical representation of A PCB holder for use on a rotor in an electric motor in accordance with various embodiments

FIG. 6 shows a cross sectional graphical representation of an installed PCB holder in accordance with various embodiments.

### DETAILED DESCRIPTION

The following detailed description is merely exemplary in nature and is not intended to limit the application and uses. Furthermore, there is no intention to be bound by any expressed or implied theory presented in the preceding technical field, background, brief summary, or the following detailed description. As used herein, the term “module” refers to any hardware, software, firmware, electronic control component, processing logic, and/or processor device, individually or in any combination, including without limitation: application-specific integrated circuit (ASIC), a field-programmable gate array (FPGA), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, lookup tables, or the like, which may carry out a variety of functions under the control of one or more microprocessors or other control devices. In addition, those skilled in the art will appreciate that embodiments of the present disclosure may be practiced in conjunction with any number of systems and that the systems described herein are merely exemplary embodiments of the present disclosure.

For the sake of brevity, conventional techniques related to signal processing, data transmission, signaling, control, machine learning, image analysis, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

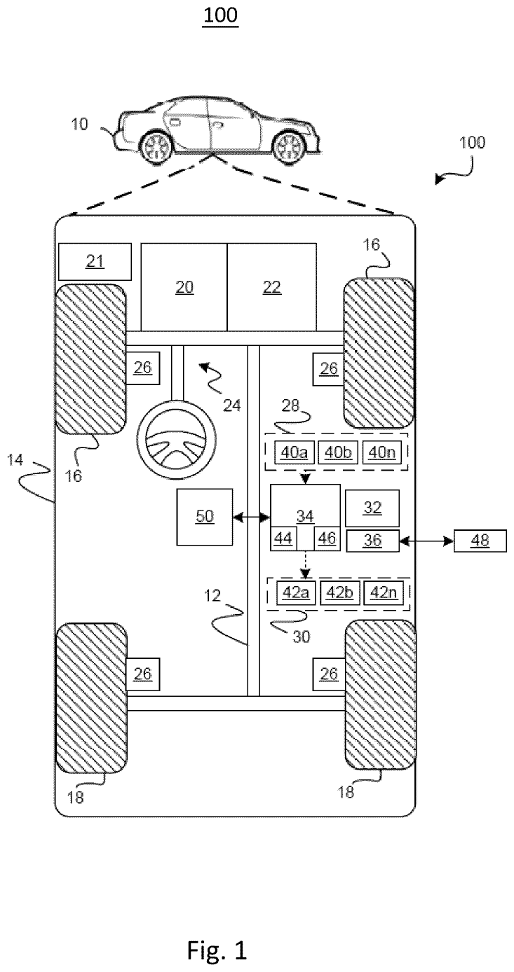

With reference to FIG. 1, a vehicle 10 is shown employing one or more electric vehicle motors and battery systems, and more particularly employs a dynamically adjustable traction inverter to utilize adjustable dead time to minimize the conduction losses while simultaneously preventing any shoot-through in the inverter phase legs by utilizing power devices with minimum switching times and gate charge to enable shorter dead times

As shown in FIG. 1, the vehicle 10 generally includes a chassis 12, a body 14, front wheels 16, and rear wheels 18. The body 14 is arranged on the chassis 12 and substantially encloses components of the vehicle 10. The body 14 and the chassis 12 may jointly form a frame. The wheels 16 and 18 are each rotationally coupled to the chassis 12 near a respective corner of the body 14.

The vehicle 10 is depicted in the illustrated embodiment as a passenger car, but it should be appreciated that any other vehicle including motorcycles, trucks, sport utility vehicles (SUVs), recreational vehicles (RVs), marine vessels, aircraft, etc., can also be used. In various embodiments, the vehicle 10 can be an autonomous vehicle that is automatically controlled to carry passengers and/or cargo from one location to another. In an exemplary embodiment, the vehicle 10 can have an automation system of Level Two or higher. A Level Two automation system indicates “partial automation.” However, in other embodiments, the autonomous vehicle may be a so-called Level Three, Level Four or Level Five automation system. A Level Three automation system indicates conditional automation. A Level Four system indicates “high automation,” referring to the driving mode-specific performance by an automated driving system of all aspects of the dynamic driving task, even when a human driver does not respond appropriately to a request to intervene. A Level Five system indicates “full automation”, referring to the full-time performance by an automated driving system of all aspects of the dynamic driving task under all roadway and environmental conditions that can be managed by a human driver.

However, it is to be understood that the vehicle 10 may also be a conventional vehicle without any autonomous driving functions. The vehicle 10 may implement the functions and methods for generating a virtual view having harmonized color in accordance with the present disclosure.

As shown, the vehicle 10 generally includes a propulsion system 20, a transmission system 22, a steering system 24, a brake system 26, a sensor system 28, an actuator system 30, at least one data storage device 32, at least one controller 34, and a communication system 36. The propulsion system 20 may, in various embodiments, include an internal combustion engine, an electric machine such as a traction motor, a fuel cell propulsion system, and/or a combination thereof. The transmission system 22 is configured to transmit power from the propulsion system 20 to the vehicle wheels 16 an 18 according to selectable speed ratios. According to various embodiments, the transmission system 22 may include a step-ratio automatic transmission, a continuously-variable transmission, a manual transmission, or any other appropriate transmission.

The brake system 26 is configured to provide braking torque to the vehicle wheels 16 and 18. The brake system 26 may, in various embodiments, include friction brakes, brake by wire, a regenerative braking system such as an electric machine, and/or other appropriate braking systems. The steering system 24 influences a position of the of the vehicle wheels 16 and 18. While depicted as including a steering wheel for illustrative purposes, in some embodiments contemplated within the scope of the present disclosure, the steering system 24 may not include a steering wheel.

The sensor system 28 includes one or more sensing devices 40a-40n that sense observable conditions of the exterior environment and/or the interior environment of the vehicle 10. The sensing devices 40a-40n can include, but are not limited to, radars, lidars, global positioning systems (GPS), optical cameras, thermal cameras, ultrasonic sensors, and/or other sensors. The sensing devices 40a-40n are further configures to sense observable conditions of the vehicle 10. The sensing devices 40a-40n can include, but are not limited to, speed sensors, position sensors, inertial measurement sensors, temperature sensors, pressure sensors, etc.

The actuator system 30 includes one or more actuator devices 42a-42n that control one or more vehicle features such as, but not limited to, the propulsion system 20, the transmission system 22, the steering system 24, and the brake system 26. In various embodiments, the vehicle features can further include interior and/or exterior vehicle features such as, but are not limited to, doors, a trunk, and cabin features such as air, music, lighting, etc. (not numbered).

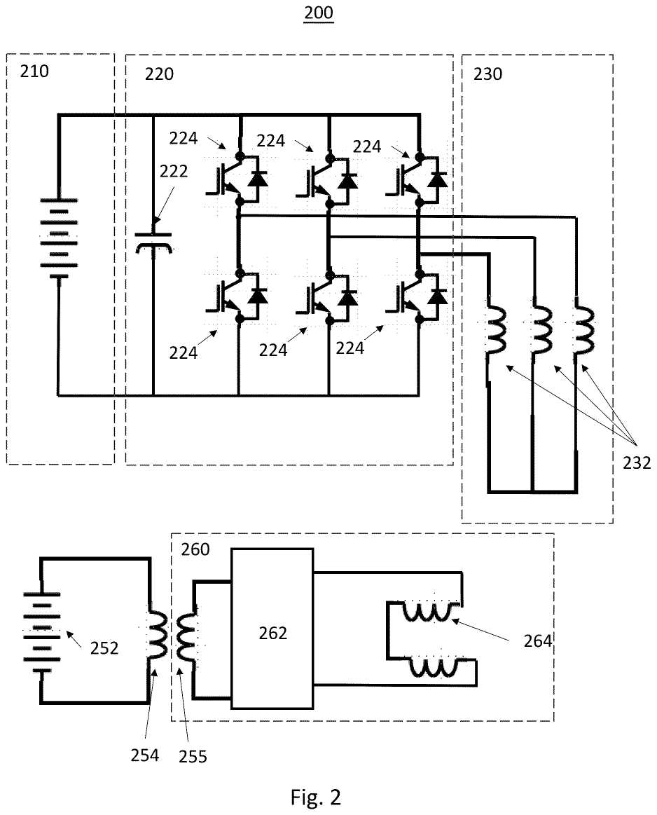

The communication system 36 is configured to wirelessly communicate information to and from other entities 48, such as but not limited to, other vehicles (“V2V” communication,) infrastructure (“V2I” communication), remote systems, and/or personal devices (described in more detail with regard to FIG. 2). In an exemplary embodiment, the communication system 36 is a wireless communication system configured to communicate via a wireless local area network (WLAN) using IEEE 802.11 standards or by using cellular data communication. However, additional, or alternate communication methods, such as a dedicated short-range communications (DSRC) channel, are also considered within the scope of the present disclosure. DSRC channels refer to one-way or two-way short-range to medium-range wireless communication channels specifically designed for automotive use and a corresponding set of protocols and standards.

The data storage device 32 stores data for use in automatically controlling functions of the vehicle 10. In various embodiments, the data storage device 32 stores defined maps of the navigable environment. The defined maps may include a variety of data other than road data associated therewith, including elevation, climate, lighting, etc. In various embodiments, the defined maps may be predefined by and obtained from a remote system (described in further detail with regard to FIG. 2). For example, the defined maps may be assembled by the remote system and communicated to the vehicle 10 (wirelessly and/or in a wired manner) and stored in the data storage device 32. As can be appreciated, the data storage device 32 may be part of the controller 34, separate from the controller 34, or part of the controller 34 and part of a separate system.

The controller 34 includes at least one processor 44 and a computer readable storage device or media 46. The processor 44 can be any custom made or commercially available processor, a central processing unit (CPU), a graphics processing unit (GPU), an auxiliary processor among several processors associated with the controller 34, a semiconductor based microprocessor (in the form of a microchip or chip set), a macroprocessor, any combination thereof, or generally any device for executing instructions. The computer readable storage device or media 46 may include volatile and nonvolatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 34 in controlling and executing functions of the vehicle 10.

The instructions may include one or more separate programs, each of which comprises an ordered listing of executable instructions for implementing logical functions. The instructions, when executed by the processor 44, receive and process signals from the sensor system 28, perform logic, calculations, methods and/or algorithms for automatically controlling the components of the vehicle 10, and generate control signals to the actuator system 30 to automatically control the components of the vehicle 10 based on the logic, calculations, methods, and/or algorithms. Although only one controller 34 is shown in FIG. 1, embodiments of the vehicle 10 can include any number of controllers 34 that communicate over any suitable communication medium or a combination of communication mediums and that cooperate to process the sensor signals, perform logic, calculations, methods, and/or algorithms, and generate control signals to automatically control features of the vehicle 10.

In various embodiments, one or more instructions of the controller 34 are embodied in the surround view display system 100 and, when executed by the processor 44, process image data from at least one optical camera of the sensor system 28 to extract features from the images in order to determine the ground plane. The instructions, when executed by the processor 44, use the ground plane to determine camera alignment information. The camera alignment information is then used to assemble the image data to form a surround view from a defined perspective. In various embodiments, the sensing devices 40a to 40n include N (one or more) cameras that sense an external environment of the vehicle 10 and generate the image data (e.g., optical cameras that are configured to capture color pictures of the environment). The cameras are disposed so that they each cover a certain field of view of the vehicle's surroundings. The image data from each camera is assembled into a surround view based on, for example, the pose and the location of the camera relative to the vehicle and relative to the ground.

It will be appreciated that the controller 34 may otherwise differ from the embodiments depicted in FIG. 1. For example, the controller 34 may be coupled to or may otherwise utilize one or more remote computer systems and/or other control systems, for example as part of one or more of the above-identified vehicle devices and systems. It will be appreciated that while this exemplary embodiment is described in the context of a fully functioning computer system, those skilled in the art will recognize that the mechanisms of the present disclosure are capable of being distributed as a program product with one or more types of non-transitory computer-readable signal bearing media used to store the program and the instructions thereof and carry out the distribution thereof, such as a non-transitory computer readable medium bearing the program and containing computer instructions stored therein for causing a computer processor (such as the processor 44) to perform and execute the program. Such a program product may take a variety of forms, and the present disclosure applies equally regardless of the particular type of computer-readable signal bearing media used to carry out the distribution. Examples of signal bearing media include recordable media such as floppy disks, hard drives, memory cards and optical disks, and transmission media such as digital and analog communication links. It will be appreciated that cloud-based storage and/or other techniques may also be utilized in certain embodiments. It will similarly be appreciated that the computer system of the controller 34 may also otherwise differ from the embodiment depicted in FIG. 1, for example in that the computer system of the controller 34 may be coupled to or may otherwise utilize one or more remote computer systems and/or other control systems.

Turning now to FIG. 2, a schematic representation of an EV propulsion system 200 is shown. The schematic is representative of the battery 210, the inverter 220 and the drive motor 230. The battery 210 is configured to provide DC power to the inverter circuitry 220. The inverter 220 is configured to receive the DC power from the battery 210 and to transform the DC power into a three-phase AC current required by the electric motor 230. The inverter 220 rapidly switches the plurality of power switching devices 224, such as transistors, in a predetermined sequence, generating a pulsating DC output. In some exemplary embodiments, filters, such as a decoupling capacitor 222 placed between the power and ground pins of the inverter 220, to filter out noise and maintain stable power supply voltage during switching, or one or more load capacitors or inductors to remove unwanted harmonics, resulting in a clean, three-phase AC waveform at the inverter 220. Each phase carries a distinct AC current, meticulously orchestrated to create a rotating magnetic field within the motor 230. Each of the windings 232 in the stators of the drive motor 230 are connected to one of these three phase currents. As the current flows through the windings 232, it creates a magnetic field. In the drive motor 230, the rotating magnetic field from the stators interact with the windings 264 in the rotor 260 of the drive motor 230 which in turn creates a force according to Lenz's Law. This force causes the rotor 260 to try and align itself with the rotating magnetic field, resulting in continuous rotation of the motor shaft. This rotating field is the driving force behind the motor shaft's rotation, ultimately propelling the vehicle forward. The inverter's control system allows for precise manipulation of the AC output's frequency and voltage. This fine-tuned control enables the system to precisely regulate the motor's speed and torque, ensuring smooth, efficient, and optimized operation of the EV.

While rotors 260 have typically employed permanent magnets, such as neodymium magnets, electromagnetic rotors offer several distinct advantages over permanent magnet rotors in motor applications. Electromagnetic rotors 260 allow for dynamic control of the magnetic field strength. This provides greater flexibility in adjusting motor performance, such as speed, torque, and efficiency. Electromagnetic rotors 260 can be reversed, enabling the motor to operate in both directions without requiring mechanical modifications. The ability to control the magnetic field strength allows for more precise control of the motor's characteristics, making it suitable for applications that require fine adjustments. In certain cases, electromagnetic rotors 260 may be more cost-effective than permanent magnet rotors, especially for large-scale production.

The electromagnetic rotor 260 receives AC power from an AC power source 252, via inductive power transfer (IPT). IPT is a technology that enables the transfer of electrical energy between two coils 254, 255 without physical contact. For electric motors, IPT offers a solution for powering rotating components, eliminating the need for traditional conductive connections and associated maintenance burdens. An AC power is applied to a transmitter coil 254, generating a time-varying magnetic field. A receiver coil 255, placed in proximity to the transmitter coil 254, experiences this magnetic field. According to Faraday's Law of Electromagnetic Induction, a voltage is induced in the receiver coil 255. The induced voltage can be used to power one or more electromagnetic windings 264 in the rotor in addition to other electrical components.

Since the current inducted into the receiving coil 255 is AC, it must be converted to DC to power the electromagnetic windings 264 in the rotor 260. This conversion can be made with a rectifier 262 physically located on the rotor 260. While the rectifier 262 can be powered by the AC received from the receiving coil 255, locating a printed circuit board in the harsh environmental conditions of an electric motor rotor 260 presents unique challenges for electric component cooling and the like.

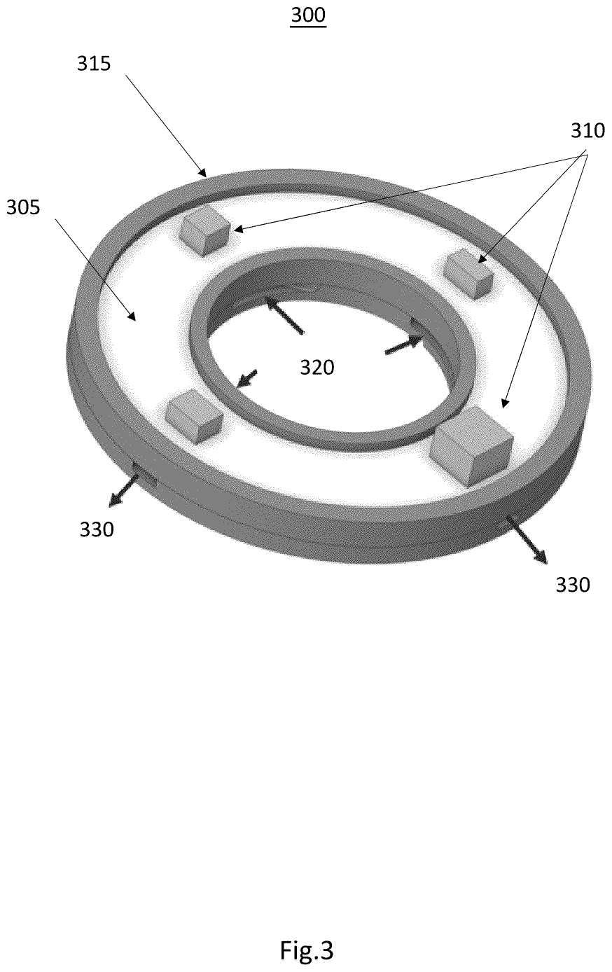

Turning now to FIG. 3, a graphical representation of an electronics package 300 for use on a rotor in an electric motor is shown. The exemplary electronics package 300 includes a printed circuit board (PCB) 305 affixed into a PCB holder 315. Various components 310, such as power switching components, are affixed to the PCB 305. In the exemplary configuration, A cooling fluid is strategically directed to the individual electrical components 310 based on their unique heat dissipation requirements and temperature tolerances. Integrated fluid channels within the PCB holder 315, which also serves as a mounting and orientation structure within the rotor drive shaft, facilitate efficient heat transfer. Electronic components 310 can be strategically positioned within the fluid flow path to maximize heat transfer coefficient. Fluid flow can be carefully regulated at the outlet 330 to ensure complete component immersion while maintaining optimal flow rate. To enhance cooling efficiency, the PCB 305 can incorporate an aluminum backing with etched or machined cooling channels. In some exemplary embodiments, the PCB 305 can be mounted outside of the rotor shaft. For example, the PCB 305 can be mounted within a housing that is mechanically affixed to a rotor housing or electric motor housing.

The rotating aspect of the electronics package 300 affixed to rotor shaft presents a unique challenge for effectively cooling these various components 310 during operation. To address this challenge, the PCB holder 315 is equipped with one or more fluid channels having channel inlets 320 and channel outlets 330. In some exemplary embodiments, a shaft of the rotor (not shown) is positioned within the inner diameter of the PCB holder 315. The shaft can have corresponding fluid outlets aligned with the channel inlets 320 of the PCB holder 315. A cooling fluid, such as air, coolant or oil, can be introduced into the shaft such that the coolant fluid flows out of the fluid outlets, into the channel inlets 320, through the cooling channels within the PCB holder 315, the cooling fluid then being expelled from the channel outlets 330. Advantageously, this configuration concentrates the flow of cooling fluid under the various components 310, thereby more effectively cooling the various components.

The innovative design of the electronics package leverages lower thermal resistance to enable fluid cooling of the electronic components 310. By strategically placing flow channels within the integrated PCB 305 and PCB holder 315, heat can be efficiently dissipated, reducing the need for excessive cooling fluid or higher operating temperatures. This approach allows for the potting of electronic components 310 on one side of the PCB 305 while effectively cooling the opposing side of the PCB 305, benefiting applications with high g-loads and vibration concerns. The PCB holder 315 can provide additional advantages such as ease of PCB assembly, retention, potting, and handling protection, contributing to a more reliable and cost-effective cooling solution.

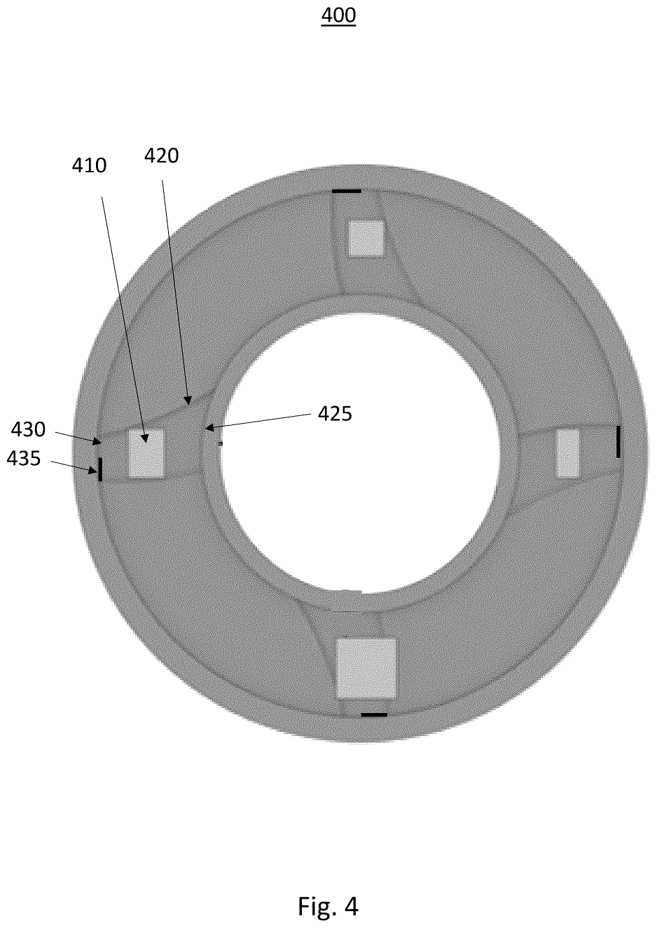

Turning now to FIG. 4, a graphical representation of a cross section of the PCB holder 400 is shown. The PCB holder 400 is shown having a fluid channel 420 running between an inner diameter of the PCB holder 400 and an outer diameter of the PCB holder. Each of the fluid channels 420 is positioned proximate to a component 410 that requires cooling. In some exemplary embodiments, the component 410 can be positioned within the flow of the fluid within the fluid channel 420. Alternatively, the component 410 can be affixed to an outer surface of the PCB and can have a thermally conductive material between the fluid channel 420 and the component 410 to facilitate cooling of the component 410.

In some exemplary embodiments, a local restriction 435 can be imposed at the outlet of the passage. To optimize oil flow and coverage, the passage widens into a funnel-like shape prior to the restriction. This design promotes adequate oil coverage near the electronic component while limiting the overall oil flow rate. While a simple funnel shape can be effective in some exemplary embodiments, it may result in increased energy consumption for pumping the oil. By incorporating a wider passage before the restriction point, both effective oil coverage and controlled flow can be achieved, potentially reducing energy expenditure.

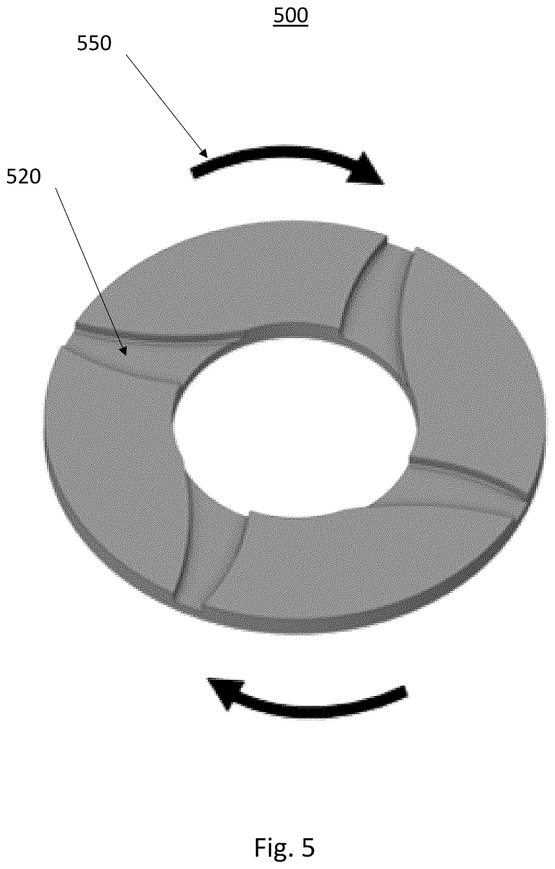

Turning now to FIG. 5, a graphical representation of A PCB holder 500 for use on a rotor in an electric motor is shown. The PCB holder is shown with the various fluid channels 520 and the direction of rotation 550 of the PCB holder 500 when mechanically coupled to the rotor shaft. In some exemplary embodiments, the fluid channels can narrow as they funnel from the inner diameter gets to the outer diameter. This narrowing can be used to regulate pressure and flow rate. In this narrowing configuration, the flow rate is regulated by the cross sectional area of the fluid channel 520 at the outer diameter. Advantageously, this configuration further insures that the fluid channel 520 is filled with fluid during rotation, thereby maximizing heat transfer from the component to the fluid. In some exemplary embodiments, the shape of the fluid channel 520 can be adjusted, such as a curved or parabolic shape, in order to further regulate the flow of the fluid through the fluid channel 520. In some exemplary embodiments, the narrowing of the fluid channels can occur locally at the very end of the fluid channel, allowing the fluid channel to stay wide near the component but the restriction at the end keeps the fluid channel f ully flooded with oil.

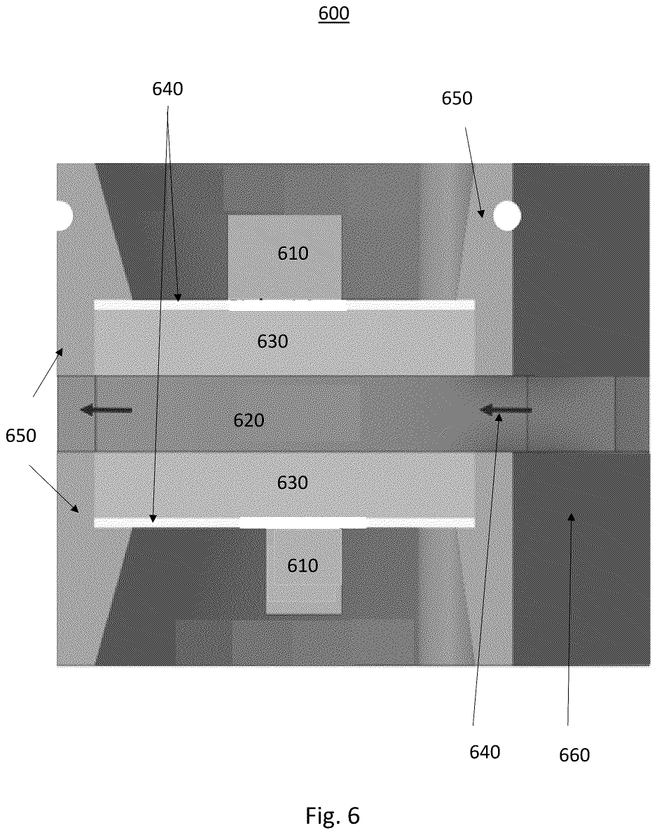

Turning now to FIG. 6, a cross sectional graphical representation of an installed PCB holder 600 on a rotational shaft 660 is shown. The cross sectional view is illustrative of the fluid channel 620 and two PCBs 640 each having a thermally conductive layer 630. Components 610, such as switching transistors or the like, as shown mounted to the PCBs 640. In some exemplary embodiments, the PCB 640 and the thermally conductive layer 630 can be a metal core circuit board. In this exemplary embodiment, the thermally conductive layer 630 is in direct connection with the fluid in the fluid channel 620, thereby maximizing heat transfer from the component 610 to the fluid. In some exemplary embodiments, the housing 650 can be constructed from an electrically insulating material, such as ceramic or plastic.

This exemplary PCB holder 600 presents an innovative cooling solution for the power electronics system within a high-speed SEM wireless power transmission system. The housing 650 incorporates integrated fluid channels 620 designed to directly contact PCB components 610, eliminating the need for thermal interface materials and reducing thermal resistance. By optimizing channel geometry and flow rates, this design achieves efficient heat dissipation while minimizing fluid consumption. The housing 650 is engineered to maintain electrical isolation, facilitate component assembly, and prevent fluid leakage, ensuring a reliable and high-performance cooling system.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A printed circuit board holder for use in a rotational application comprising:
the printed circuit board holder configured to be mechanically affixed to a rotor shaft of an electric motor having at least one fluid channel running from an interior diameter surface to an exterior diameter surface;
a printed circuit board mechanically affixed to a planar surface of the printed circuit board holder wherein the printed circuit board has a thermally conductive layer in contact with the printed circuit board holder;
a component mounted to the printed circuit board such that the component is positioned over the at least one fluid channel and wherein a thermal energy generated by the component is thermally conducted from the component to a fluid within the at least one fluid channel via the thermally conductive layer.

2. The printed circuit board holder for use in the rotational application of claim 1, wherein a first cross sectional area of the at least one fluid channel is greater at the interior diameter surface than a second cross sectional area of the at least one fluid channel at the exterior diameter surface.

3. The printed circuit board holder for use in the rotational application of claim 1, wherein the fluid is an oil.

4. The printed circuit board holder for use in the rotational application of claim 1, wherein the fluid is a non-conductive coolant.

5. The printed circuit board holder for use in the rotational application of claim 1, wherein the fluid is a gas.

6. The printed circuit board holder for use in the rotational application of claim 1, wherein a first width of the at least one fluid channel is the same as a second width of the component.

7. The printed circuit board holder for use in the rotational application of claim 1, wherein the fluid is pumped into the rotor shaft and exits at a fluid port on the rotor shaft aligned with an interior fluid channel port located on the interior diameter surface of the printed circuit board holder.

8. The printed circuit board holder for use in the rotational application of claim 1, wherein the at least one fluid channel has a backswept shape.

9. The printed circuit board holder for use in the rotational application of claim 1, wherein the printed circuit board holder is fabricated from a non-conductive material and has at least one alignment post for aligning the printed circuit board and a plurality of retention hooks for retaining the printed circuit board after the printed circuit board is pressure fit into the printed circuit board holder.

10. A method of thermally regulating a printed circuit board holder for use in a rotational application comprising,
mechanically coupling the printed circuit board holder having an interior diameter surface and an exterior diameter surface over a rotor shaft, such that the rotor shaft contacts the interior diameter surface and wherein a fluid port on the rotor shaft aligns with an interior fluid channel port on the interior diameter surface, and wherein the printed circuit board holder further includes a fluid channel running from the interior fluid channel port to an exterior fluid channel port on the exterior diameter surface;
affixing a printed circuit board to a first edge of the printed circuit board holder such that a thermally conductive layer of the printed circuit board is in contact with the printed circuit board holder and where a component is mounted to a surface opposite to the thermally conductive layer and wherein the component is positioned on the printed circuit board such that the component located over the fluid channel.

11. The method of thermally regulating the printed circuit board holder for use in the rotational application of claim 10, wherein an edge of the printed circuit board holder is taller than the printed circuit board with the component.

12. The method of thermally regulating the printed circuit board holder for use in the rotational application of claim 10 wherein a first slot in the printed circuit board holder and a second slot in the thermally conductive layer of the printed circuit board from the fluid channel.

13. The method of thermally regulating the printed circuit board holder for use in the rotational application of claim 10 wherein the interior diameter surface has a varying local radius such that a fluid is pressurized at a point of largest local radius and wherein the point of largest local radius is located at the interior fluid channel port.

14. The method of thermally regulating the printed circuit board holder for use in the rotational application of claim 10 wherein a second printed circuit board is affixed to a second edge of the printed circuit board holder opposite of the printed circuit board.

15. The method of thermally regulating the printed circuit board holder for use in the rotational application of claim 10 wherein the printed circuit board includes a rectifier for converting an inductively coupled alternating current to a direct current for powering an electromagnet.

16. The method of thermally regulating the printed circuit board holder for use in the rotational application of claim 10 wherein a first width of the fluid channel is the same as a second width of the component.

17. The method of thermally regulating the printed circuit board holder for use in the rotational application of claim 10 wherein a first cross sectional area of the fluid channel at the interior diameter surface is greater than a second cross sectional area of the fluid channel at the exterior diameter surface.

18. The method of thermally regulating the printed circuit board holder for use in the rotational application of claim 10 wherein a cooling fluid flows through the fluid channel and wherein the colling fluid is at least one of a gas, an oil and a dielectric coolant.

19. An electric motor comprising:
a rotor having a plurality of electromagnets,
a printed circuit board holder configured to be mechanically affixed at an interior diameter surface to a rotor shaft of an electric motor having a fluid channel running from the interior diameter surface to an exterior diameter surface;
a printed circuit board mechanically affixed to a planar surface of the printed circuit board holder wherein the printed circuit board has a thermally conductive layer in contact with the printed circuit board holder;
a rectifier circuit for converting an inductively coupled alternating current to a direct current for powering an electromagnet, wherein the rectifier circuit is mounted to the printed circuit board such that the rectifier circuit is positioned over the fluid channel and wherein a thermal energy generated by the rectifier circuit is thermally conducted from the rectifier circuit to a fluid within the fluid channel via the thermally conductive layer.

20. The electric motor of claim 19, wherein a first cross sectional area of the fluid channel is greater at the interior diameter surface than a second cross sectional area of the fluid channel at the exterior diameter surface.
